(19) United States
(12) Patent Application Publication
(10) Pub. No.: US 2024/0222327 A1
(43) Pub. Date: Jul. 4, 2024

(54) ELECTRONIC DEVICE

(71) Applicant: Innolux Corporation, Miaoli County (TW)

(72) Inventor: Chia-Ping Tseng, Miaoli County (TW)

(73) Assignee: Innolux Corporation, Miaoli County (TW)

(21) Appl. No.: 18/531,720

(22) Filed: Dec. 7, 2023

Related U.S. Application Data
(60) Provisional application No. 63/435,554, filed on Dec. 28, 2022.

(30) Foreign Application Priority Data
Sep. 6, 2023 (CN) 202311145609.3

(51) Int. Cl. H01L 25/065; H01L 23/00; H01L 23/498

(52) U.S. Cl. CPC H01L 25/0655; H01L 23/49838; H01L 24/32; H01L 24/48; H01L 2224/32147; H01L 2224/32235; H01L 2224/48137; H01L 2224/48145; H01L 2924/01029; H01L 2924/01042; H01L 2924/1306

(57) ABSTRACT

An electronic device includes a substrate, a conductive structure, a first passivation layer, and an electronic component. The conductive structure is provided on the substrate and has at least one discontinuous part. The first passivation layer is provided on the conductive structure and has a first opening. The electronic component is provided on the conductive structure. The electronic component is electrically connected to the conductive structure through the first opening. The at least one discontinuous part overlaps the first opening. The electronic device in the embodiments of the disclosure may improve the problem of the intermetallic compound layer affecting the formation of the conductive member.

### CROSS-REFERENCE TO RELATED APPLICATION

This application claims the priority benefit of the U.S. provisional application Ser. No. 63/435,554, filed on Dec. 28, 2022, and China application serial no. 202311145609.3, filed on Sep. 6, 2023. The entirety of each of the above-mentioned patent applications is hereby incorporated by reference herein and made a part of this specification.

### BACKGROUND

### Technical Field

The disclosure relates to an electronic device, and more particularly, to an electronic device that may improve the problem of the intermetallic compound layer affecting the formation of the conductive member.

### Description of Related Art

Electronic devices or splicing electronic devices has been widely applied in different fields such as communication, display, vehicle, or aviation. With the vigorous development of electronic devices, the electronic devices are becoming thinner and lighter, which has led to higher requirements for the reliability or quality of the electronic devices.

### SUMMARY

The disclosure provides an electronic device that may improve the problem of the intermetallic compound layer affecting the formation of the conductive member.

According to the embodiment of the disclosure, the electronic device includes a substrate, a conductive structure, a first passivation layer, and an electronic component. The conductive structure is provided on the substrate and has at least one discontinuous part. The first passivation layer is provided on the conductive structure and has a first opening. The electronic component is provided on the conductive structure. The electronic component may be electrically connected to the conductive structure through the first opening. The at least one discontinuous part overlaps the first opening.

### BRIEF DESCRIPTION OF THE DRAWINGS

The accompanying drawings are included to provide a further understanding of the disclosure, and are incorporated in and constitute a part of this specification. The drawings illustrate embodiments of the disclosure, and together with the description serve to explain principles of the disclosure.

FIG. 1A is a cross-sectional schematic view of the electronic device in the first embodiment of the disclosure.

FIG. 1B is an enlarged schematic view of the area RE of the electronic device in FIG. 1A.

FIG. 2 is a partial cross-sectional schematic view of the electronic device in the second embodiment of the disclosure.

FIG. 3 is a partial cross-sectional schematic view of the electronic device in the third embodiment of the disclosure.

FIG. 4A is a partial top schematic view of the electronic device in the fourth embodiment of the disclosure.

FIG. 4B is a partial cross-sectional schematic view of the electronic device in FIG. 4A.

FIG. 5 is a partial cross-sectional schematic view of the electronic device in the fifth embodiment of the disclosure.

FIG. 6 is a partial cross-sectional schematic view of the electronic device in the sixth embodiment of the disclosure.

FIG. 7 is a partial cross-sectional schematic view of the electronic device in the seventh embodiment of the disclosure.

### DESCRIPTION OF THE EMBODIMENTS

The disclosure can be understood by referring to the following detailed description in conjunction with the accompanying drawings. It should be noted that, for the ease of understanding by the readers and for the brevity of the accompanying drawings, multiple drawings in the disclosure only depict a portion of the electronic device, and the specific elements in the drawings are not drawn according to the actual scale. In addition, the number and size of each of the elements in the figures are for illustration purposes only, and are not intended to limit the scope of the disclosure.

In the following description and claims, words such as “comprising” and “including” are open-ended words, so they should be interpreted as meaning “including but not limited to . . . ”.

It should be understood that when an element or layer is referred to as being “on” or “connected to” another element or layer, it may be directly on or directly connected to this other element or layer, or there may be an intervening element or layer in between (indirect case). In contrast, when an element is referred to as being “directly on” or “directly connected to” another element or layer, there are no intervening elements or layers present.

Although the terms “first”, “second”, “third”, . . . may be used to describe various constituent elements, the constituent elements are not limited by the terms. The terms are only used to distinguish a single constituent element from other constituent elements in the specification. The same terms may not be used in the claim, but replaced by first, second, third . . . according to the order in which the elements are declared in the claim. Therefore, in the following description, the first constituent element may be the second constituent element in the claim.

As used herein, the terms “about,” “approximately,” “substantially,” and “roughly” generally mean within 10%, within 5%, within 3%, within 2%, within 1%, or within 0.5% of a given value or range. The quantity given here is an approximate quantity, that is, even though “about,” “approximately,” “substantially,” and “roughly” are not specified, the meaning of “about,” “approximately,” “substantially,” and “roughly” are still implied.

In some embodiments of the disclosure, terms related to joining and connecting, such as “connected”, “interconnected”, etc., unless otherwise defined, may mean that two structures are in direct contact, or may also mean that two structures are not in direct contact, in which there are other structures located between these two structures. The terms related to joining and connecting can also include the case where both structures are movable, or both structures are fixed. Furthermore, the term “coupled” includes any direct and indirect means of electrical connection.

In some embodiments of the disclosure, optical microscopy (OM), scanning electron microscope (SEM), film thickness profiler (a-step), ellipsometer, or other suitable methods may be used to measure the area, width, thickness, or height of each element, or the distance or pitch between elements. In detail, according to some embodiments, a scanning electron microscope can be used to obtain a cross-sectional structure image including a component to be measured, and to measure the area, width, thickness, or height of each element, or the distance or pitch between elements.

The electronic device of this disclosure may include a display device, an antenna device, a communication device, a sensing device, or a splicing device, but is not limited thereto. The electronic device may be a bendable or flexible electronic device. The electronic device may, for example, include a liquid crystal light emitting diode; the light emitting diode may include, for example, an organic light-emitting diode (OLED), a mini light-emitting diode (mini LED), a micro light-emitting diode (micro LED), or a quantum dot light-emitting diode (quantum dot, QD, such as QLED, QDLED), fluorescence, phosphor, or other suitable materials, and the materials can be any arrangement and combination, but not limited thereto. The antenna device may be, for example, a phase array antenna, but is not limited thereto. The splicing device may be, for example, a display splicing device or an antenna splicing device, but not limited thereto. It should be noted that, the electronic device can be any arrangement and combination of the foregoing, but not limited thereto. Hereinafter, an electronic device is used to illustrate the disclosure, but the disclosure is not limited thereto.

It should be noted that, in the following embodiments, the features in several different embodiments can be replaced, reorganized, and mixed to complete other embodiments without departing from the spirit of the disclosure. As long as the features of the various embodiments do not violate the spirit of the disclosure or conflict with one another, they can be mixed and matched arbitrarily.

References of the exemplary embodiments of the disclosure are to be made in detail.

Examples of the exemplary embodiments are illustrated in the drawings. If applicable, the same reference numerals in the drawings and the descriptions indicate the same or similar parts.

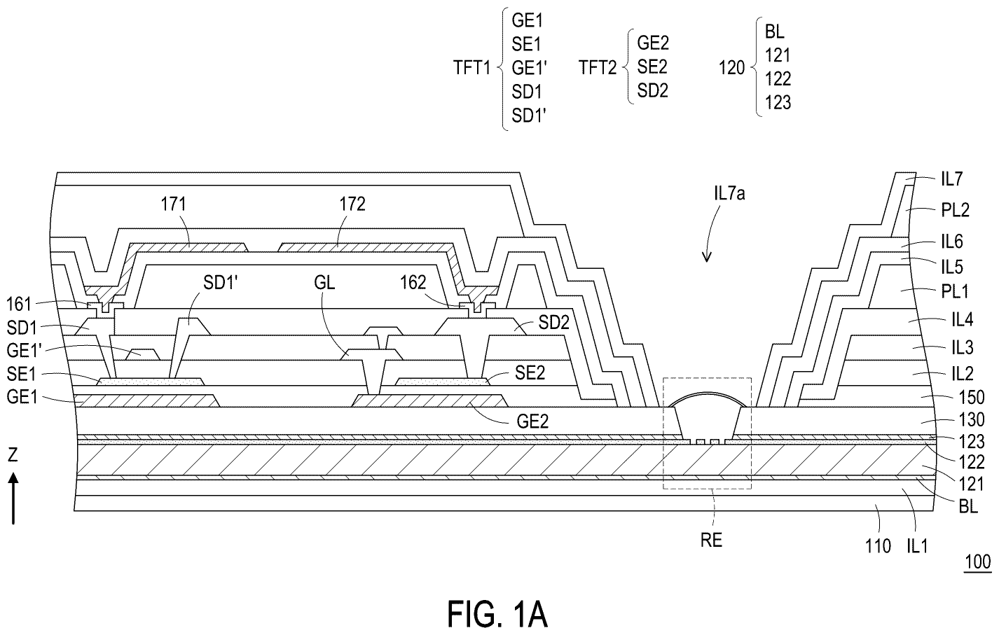

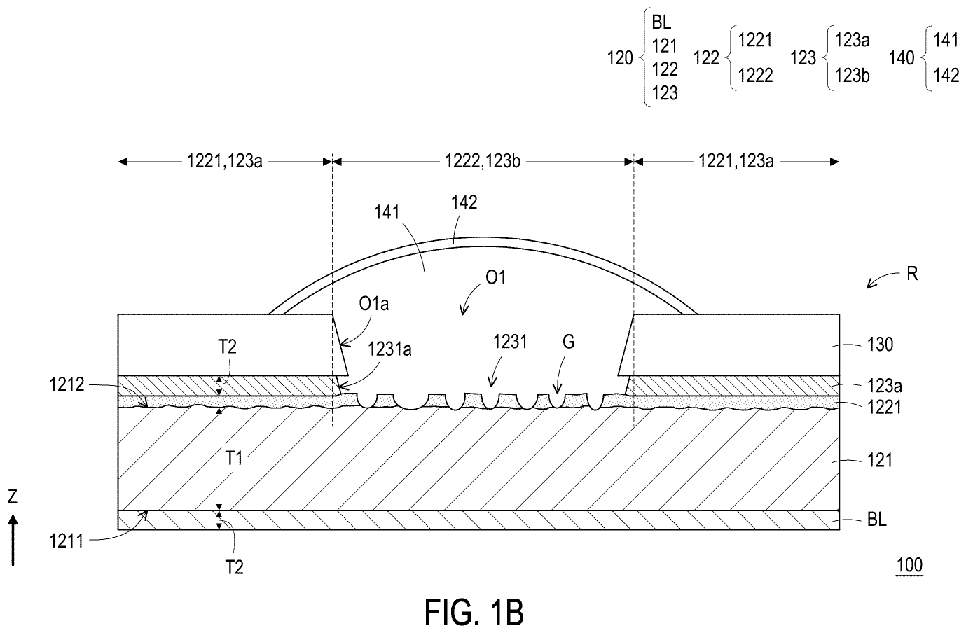

FIG. 1A is a cross-sectional schematic view of the electronic device in the first embodiment of the disclosure. FIG. 1B is an enlarged schematic view of the area RE of the electronic device in FIG. 1A.

Referring to FIG. 1A and FIG. 1B, the electronic device 100 of this embodiment includes a substrate 110, a conductive structure 120, a first passivation layer 130, and an electronic component. In this embodiment, the material of the substrate 110 may be, for example, glass or other suitable transparent substrate material, but is not limited thereto. In some embodiment, the substrate 110 may include a rigid substrate, a flexible substrate or a combination of both. For example, the material of the substrate 110 may include glass, quartz, sapphire, ceramic, polycarbonate (PC), polyimide (PI), polyethylene terephthalate (PET), other suitable substrate materials, or a combination of the foregoing, but not limited thereto.

The conductive structure 120 is provided on the substrate 110. The conductive structure 120 includes a first layer 121, a second layer 122, and a third layer 123 in order from bottom to top. The first layer 121 is provided on a bottom layer BL, the second layer 122 is provided on the first layer 121, the third layer 123 is provided on the second layer 122, and the second layer 122 is provided between the first layer 121 and the third layer 123. In other embodiments, the conductive structure 120 may further include a bottom layer BL disposed under the first layer 121.

Specifically, in this embodiment, the first layer 121 has a first surface 1211 and a second surface 1212 that are opposite to each other. The first surface 1211 faces the bottom layer BL, and the second surface 1212 faces the second layer 122.

The second layer 122 has a continuous part 1221 and a discontinuous part 1222. The continuous part 1221 may be in contact with the first layer 121 and the third layer 123. The discontinuous part 1222 may be in contact with the first layer 121 but not the third layer 123. The discontinuous part 1222 includes a gap G, which may expose a part of the first layer 121. The second layer 122 may be used to reduce the risk of the first layer 121 being oxidized or corroded. In addition, in the manufacturing method of the electronic device 100 of this embodiment, since the third layer 123 may diffuse toward the first layer 121 in the subsequent high-temperature process (e.g., the process of forming the first transistor TFT1 or the second transistor TFT2 after the first passivation layer 130 is formed, but is not limited thereto). Thus, the second layer 122 may be formed at the junction of the third layer 123 and the first layer 121, the second layer 122 is the intermetallic compound layer of the first layer 121 and the third layer 123.

The third layer 123 has a continuous part 123a and a discontinuous part 123b. The discontinuous part 123b includes an opening 1231. The opening 1231 of the discontinuous part 123b may overlap the discontinuous part 1222 and the gap G in the normal direction Z of the substrate 110, so that the opening 1231 may expose the discontinuous part 1222 and a part of the first layer 121. The opening 1231 has a side wall 1231a. In this embodiment, the setting of the third layer 123 may be used to reduce the risk of peeling due to the large difference in coefficient of thermal expansion (CTE) between the first layer 121 and the first passivation layer 130.

In this embodiment, the thickness T1 of the first layer 121 may be greater than the thickness T2 of the bottom layer BL and the third layer 123. The thickness T1 is, for example, the thickness of the first layer 121 measured along the normal direction Z of the substrate 110, and the thickness T2 is, for example, the thickness of the bottom layer BL or the third layer 123 measured along the normal direction Z of the substrate 110. For example, the thickness T1 of the first layer 121 may be, for example, 0.5 micron (m) to 12 microns, and the thickness T2 of the bottom layer BL and the third layer 123 may be, for example, 10 nanometers (nm) to 0.5 micron, but is not limited thereto. The thickness of the second layer 122 is uneven. In addition, in this embodiment, the material of the first layer 121 may be, for example, copper; the material of the second layer 122 may be, for example, titanium copper; and the material of the bottom layer BL and the third layer 123 may be, for example, titanium, but is not limited thereto.

The first passivation layer 130 is provided on the conductive structure 120. The first passivation layer 130 has a first opening O1. The first opening O1 may overlap the opening 1231 of the discontinuous part 123b and the discontinuous part 1222 in the normal direction Z of the substrate 110. The first opening O1 has a side wall O1a, and the side wall O1a is not cut flush with the side wall 1231a. In this embodiment, the first passivation layer 130 may be a single-layer structure or a multi-layer structure, and the material of the first passivation layer 130 may include organic material, inorganic material (e.g., silicon nitride or silicon oxide) or a combination of foregoing, but is not limited thereto.

The electronic component is provided on the conductive structure 120. The electronic component may be electrically connected to the conductive structure 120 through the first opening O1. In this embodiment, the electronic component may include passive elements and/or active elements, such as capacitors, resistors, inductors, diodes, transistors, etc., but is not limited thereto. The diodes may include light-emitting diodes, photodiodes, or varactor diodes.

In this embodiment, the electronic device 100 further includes a conductive member 140, a dielectric layer IL1, a second passivation layer 150, a first transistor TFT1, a second transistor TFT2, a gate line GL, a dielectric layer IL2, a dielectric layer IL3, a dielectric layer IL4, a metal pad 161, a metal pad 162, a protective layer PL1, a dielectric layer IL5, a metal layer 171, a metal layer 172, a dielectric layer IL6, a protective layer PL2, and a dielectric layer IL7.

Specifically, the conductive member 140 includes a first conductive layer 141 and a second conductive layer 142. The first conductive layer 141 is provided on the first passivation layer 130, in the first opening O1, in the opening 1231, and in the gap G. The first conductive layer 141 of the conductive member 140 may be in contact with and electrically connected to the first layer 121 of the conductive structure 120. The second conductive layer 142 is provided on the surface of the first conductive layer 141. In this embodiment, the material of the first conductive layer 141 may be, for example, nickel, and the material of the second conductive layer 142 may be, for example, gold, but is not limited thereto.

The dielectric layer IL1 is provided between the bottom layer BL and the substrate 110. The first transistor TFT1 and the second transistor TFT2 are provided on the first passivation layer 130. The first transistor TFT1 includes a gate GE1, a semiconductor SE1, a gate GE1′, a source SD1, and a drain SD1′, and the second transistor TFT2 includes a gate GE2, a semiconductor SE2, and a drain SD2. The gate GE1 and the gate GE2 are provided on the first passivation layer 130. The second passivation layer 150 is provided on the gate GE1 and the gate GE2, and the second passivation layer 150 may cover the first passivation layer 130. The semiconductor SE1 and the semiconductor SE2 are provided on the second passivation layer 150. The dielectric layer IL2 is provided on the semiconductor SE1 and the semiconductor SE2, and the dielectric layer IL2 may cover the second passivation layer 150. The gate GE1′ and the gate line GL are provided on the dielectric layer IL2, and the gate line GL may be electrically connected to the semiconductor SE2. The dielectric layer IL3 is provided on the gate GE1′ and the gate line GL, and the dielectric layer IL3 may cover the dielectric layer IL2. The source SD1, the drain SD1′, and the drain SD2 are provided on the dielectric layer IL3. The source SD1 and the drain SD1′ may be electrically connected to the semiconductor SE1 respectively, and the drain SD2 may be electrically connected to the semiconductor SE2. The dielectric layer IL4 may be provided on the source SD1, the drain SD1′, and the drain SD2, and the dielectric layer IL4 may cover the dielectric layer IL3. The metal pad 161, the metal pad 162, and the protective layer PL1 are provided on the dielectric layer IL4, and the metal pad 161 and the metal pad 162 may be electrically connected to the source SD1 of the first transistor TFT1 and the drain SD2 of the second transistor TFT2, respectively. The dielectric layer IL5 is provided on the metal pad 161, the metal pad 162, and the protective layer PL1. The metal layer 171 and the metal layer 172 are provided on the dielectric layer IL5, and the metal layer 171 and the metal layer 172 may be electrically connected to the metal pad 161 and the metal pad 162, respectively. The dielectric layer IL6 is provided on the metal layer 171 and the metal layer 172, and the dielectric layer IL6 may cover the dielectric layer IL5. The protective layer PL2 is provided on the dielectric layer IL6. The dielectric layer IL7 is provided on the protective layer PL2. The dielectric layer IL7 has an opening IL7a for exposing the conductive member 140.

In this embodiment, the dielectric layer IL1, the second passivation layer 150, the dielectric layer IL2, the dielectric layer IL3, the dielectric layer IL4, the protective layer PL1, the dielectric layer IL5, the dielectric layer IL6, the protective layer PL2, and the dielectric layer IL7 may be single-layer structures multi-layer structures, and the material of the dielectric layer IL1, the second passivation layer 150, the dielectric layer IL2, the dielectric layer IL3, the dielectric layer IL4, the protective layer PL1, the dielectric layer IL5, the dielectric layer IL6, the protective layer PL2, and the dielectric layer IL7 may include organic material, inorganic material (e.g., silicon nitride or silicon oxide), or a combination of both, but is not limited thereto.

In this embodiment, the material of the semiconductor SE1 and the semiconductor SE2 may include a low-temperature polycrystalline silicon (LTPS) semiconductor, but is not limited thereto. In some embodiments, the materials of the semiconductor SE1 and the semiconductor SE2 may also include amorphous silicon semiconductor, metal oxide (e.g., indium gallium zinc oxide IGZO), other suitable materials, or combinations of the foregoing, but are not limited thereto. In some embodiments, the material of the semiconductor SE1 may be different from the material of the semiconductor SE2.

In the manufacturing method of the electronic device 100 of this embodiment, the method of forming the discontinuous part 1222 of the second layer 122 and the gap G may, for example, include but is not limited to the following steps: after stacking the stacked structure (the bottom layer BL, the first layer 121, and the third layer 123) and the first passivation layer 130 and forming the first transistor TFT1 and the second transistor TFT2, the second layer 122 is formed at the junction between the first layer 121 and the third layer 123 due to the high-temperature process; next, after forming the opening IL7a of the dielectric layer IL7 and the first opening O1 of the first passivation layer 130, dry etch and micro-etch are performed on the third layer 123 exposed by the first opening O1 to form the opening 1231; then, the second layer 122 exposed by the opening 1231 is micro-etched for a longer period of time, at this time, due to the poor etching effect of the micro-etch on the second layer 122, only a part of the second layer 122 (e.g., a thinner part) may be etched to form the gap G and expose a part of the first layer 121, and the other part of the second layer 122 (e.g., the thicker part) is not etched so as to form the discontinuous part 1222. The micro-etch may be, for example, using an acidic solution, but is not limited thereto.

Since the conductive member is not easily formed directly on the intermetallic compound layer, in the electronic device 100 of this embodiment, a part of the intermetallic compound layer is removed, the gap G is formed, and a part of the first layer 121 is exposed through increasing the processing time of the micro-etch. Thus, the conductive member 140 may be formed in the gap G, in the opening 1231, in the first opening O1, and on the first passivation layer 130, and the conductive member 140 may be in contact with the first layer 121.

In this embodiment, the electronic device 100 may be applied to a display (e.g., an organic light emitting diode display), a printed circuit board (PCB), a 5G communication device, a semiconductor packaging, an antenna device (e.g., phase array antenna or microstrip antenna), and other related products, but are not limited thereto.

Other embodiments are described below for illustrative purposes. It is to be noted that the following embodiments use the reference numerals and a part of the contents of the above embodiments, and the same reference numerals are used to denote the same or similar elements, and the description of the same technical contents is omitted. For the description of the omitted part, reference may be made to the above embodiments, and details are not described in the following embodiments.

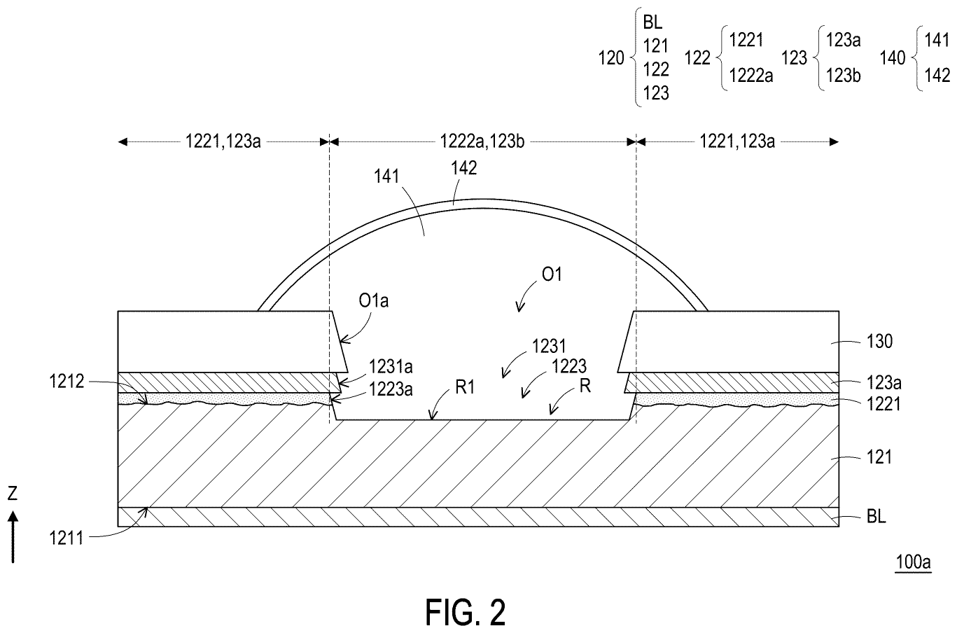

FIG. 2 is a partial cross-sectional schematic view of an electronic device according to a second embodiment of the disclosure. Referring to FIG. 2 and FIG. 1A to FIG. 1B at the same time, the electronic device 100a of this embodiment is similar to the electronic device 100 in FIG. 1A to FIG. 1B. The difference between the two is: in the electronic device 100a of this embodiment, the first layer 121 of the conductive structure 120 has a recess R, and the discontinuous part 1222a of the second layer 122 includes an opening 1223.

Specifically, referring to FIG. 2, in this embodiment, the recess R may be recessed in the second surface 1212 of the first layer 121, and the bottom surface R1 of the recess R may be lower than the second surface 1212 of the first layer 121 in the normal direction Z of the substrate 110.

The opening 1223 of the second layer 122 may be connected to the recess R to expose a part of the first layer 121. The opening 1223 has a side wall 1223a, and the side wall 1223a is not cut flush with the side wall 1231a of the opening 1231.

The first opening O1 may overlap the opening 1231, the opening 1223, and the recess R in the normal direction Z of the substrate 110.

The first conductive layer 141 of the conductive member 140 may be provided on the first passivation layer 130, in the first opening O1, in the opening 1231, in the opening 1223, and in the recess R, so that the first conductive layer 141 may be in contact with and electrically connected to the first layer 121.

In the manufacturing method of the electronic device 100 of this embodiment, the method of forming the opening 1223 of the second layer 122 and the recess R of the first layer 121 may, for example, include but is not limited to the following steps: after stacking the stacked structure (the bottom layer BL, the first layer 121, and the third layer 123) and the first passivation layer 130 and forming the first transistor TFT1 and the second transistor TFT2, the second layer 122 is formed at the junction between the first layer 121 and the third layer 123 due to the high-temperature process; next, after forming the opening IL7a of the dielectric layer IL7 and the first opening O1 of the first passivation layer 130, dry etch and micro-etch are performed on the third layer 123 exposed by the first opening O1 to form the opening 1231; then, wet etch is performed on the second layer 122 exposed by the opening 1231, at this time, since wet etch may, for example, use an etchant that does not contain fluorine and may have an etching effect on the second layer 122, in addition to etching the second layer 122 to form the opening 1223, the etchant may also etch the first layer 121 exposed by the opening 1223 to form the recess R. In addition, since the wet etch also laterally etches the third layer 123 around the opening 1231 and the second layer 122 around the opening 1223, an undercut phenomenon occurs.

Since the conductive member is not easily formed directly on the intermetallic compound layer, in the electronic device 100a of this embodiment, the intermetallic compound layer between the first opening O1 (or the opening 1231) and the first layer 121 is removed by wet etch and a part of the first layer 121 is exposed. Thus, the conductive member 140 may be formed in the recess R, in the opening 1231, in the first opening O1, and on the first passivation layer 130, and the conductive member 140 may be in contact with the first layer 121.

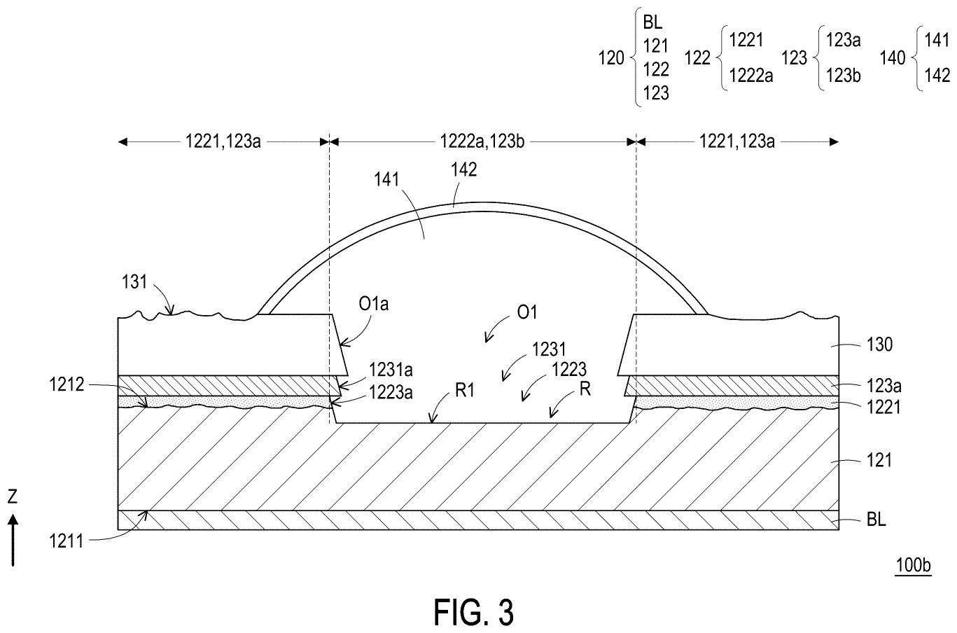

FIG. 3 is a partial cross-sectional schematic view of the electronic device in the third embodiment of the disclosure. Referring to FIG. 3 and FIG. 2 at the same time, the electronic device 100b of this embodiment is similar to the electronic device 100a in FIG. 2. The difference between the two is: in the electronic device 100b of this embodiment, the surface 131 of the first passivation layer 130 is uneven.

Specifically, referring to FIG. 3, in this embodiment, since when forming the opening 1223 of the discontinuous part 1222a of the second layer 122 and the recess R of the first layer 121, an etchant containing fluorine and may have an etching effect on the second layer 122 is used for wet etch, the surface 131 of the first passivation layer 130 is also damaged by the fluorine-containing etchant, causing the surface 131 of the first passivation layer 130 facing away from the third layer 123 to be uneven and have an increased roughness.

In some embodiments, the roughness of the surface 131 of the first passivation layer 130 may be greater than the roughness of the surface of the second passivation layer 150 as shown in FIG. 1A.

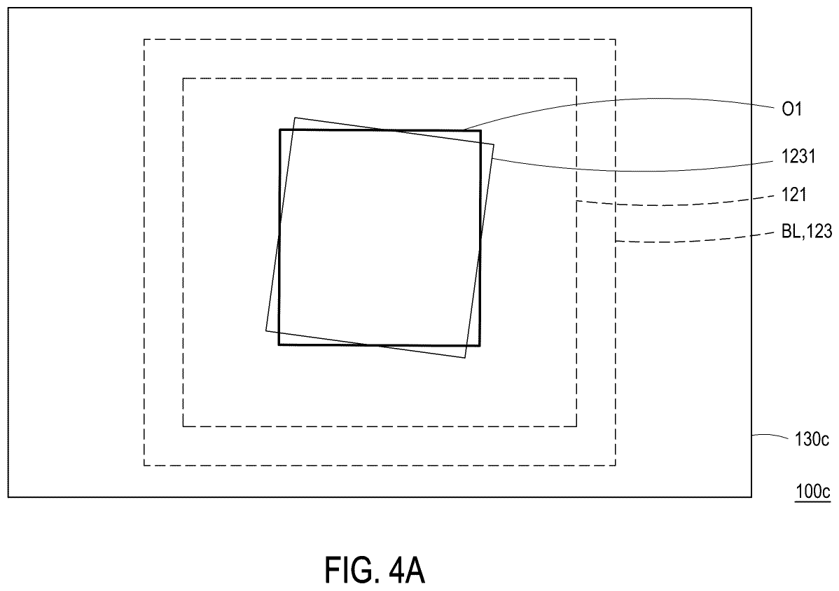

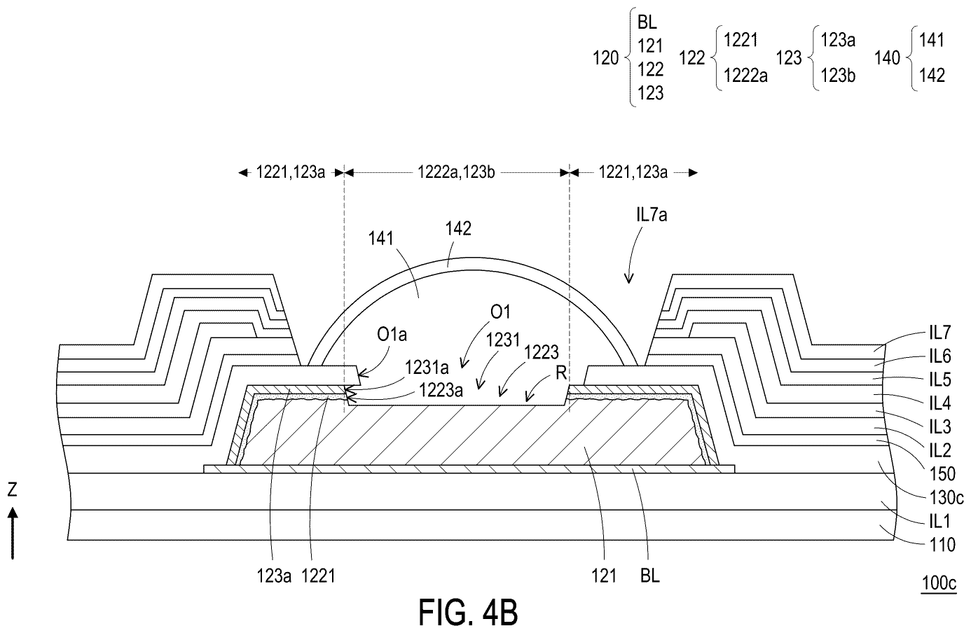

FIG. 4A is a partial top schematic view of the electronic device in the fourth embodiment of the disclosure. FIG. 4B is a partial cross-sectional schematic view of the electronic device in FIG. 4A. For clarity of the drawing and convenience of description, FIG. 4A schematically shows several elements in the electronic device 100c, such as the first passivation layer 130c and the conductive member 140, but is not limited thereto. Referring to FIG. 4A to FIG. 4B and FIG. 2 at the same time, the electronic device 100c of this embodiment is similar to the electronic device 100a in FIG. 2. The difference between the two is: in the profile of the electronic device 100c of this embodiment, the recess R of the first layer 121 is not aligned with the first opening O1 of the first passivation layer 130c.

Specifically, referring to FIG. 4A and FIG. 4B, in this embodiment, the side wall O1a on two sides of the first opening O1 of the first passivation layer 130c is not cut flush with the corresponding side wall 1231a in the opening 1231 of the third layer 123. The side wall O1a on one side (e.g., the left side in FIG. 4B) of the first opening O1 may cover the side wall 1231a on the corresponding side in the opening 1231, and the side wall O1a on the other side (e.g., the right side in FIG. 4B) of the first opening O1 may expose the corresponding side wall 1231a on the other side in the opening 1231. In other words, compared to the position of the opening 1231, the first opening O1 is displaced to the right side in FIG. 4B, causing the position of the first opening O1 not to be aligned with the opening 1231.

In addition, in this embodiment, the side wall 1231a of the opening 1231 of the third layer 123 may be cut flush with the side wall 1223a of the opening 1223 of the discontinuous part 1222a of the second layer 122.

Different from the manufacturing method of the electronic device 100a in FIG. 2, in the manufacturing method of the electronic device 100c of this embodiment: after stacking the stacked structure (the bottom layer BL, the first layer 121, and the third layer 123), and before stacking the first passivation layer 130c and forming the first transistor TFT1 (or the second transistor TFT2) (i.e., before forming the second layer 122), the opening 1231 of the third layer 123 and the recess R of the first layer 121 are first formed by etching. Thus, it is difficult for the first opening O1 of the first passivation layer 130c formed subsequently to be accurately aligned with the formed opening 1231.

Since the conductive member is not easily formed directly on the intermetallic compound layer, in the electronic device 100c of this embodiment, by forming the opening 1231 of the third layer 123 through etching before forming the second layer 122 containing the intermetallic compound, a part of the first layer 121 may be exposed and the formation of an intermetallic compound layer above the first layer 121 corresponding to the first opening O1 (or the opening 1231) in the subsequent high-temperature process may be avoided. Thus, the conductive member 140 may be formed in the recess R, in the opening 1223, in the opening 1231, in the first opening O1, and on the first passivation layer 130, and the conductive member 140 may be in contact with the first layer 121.

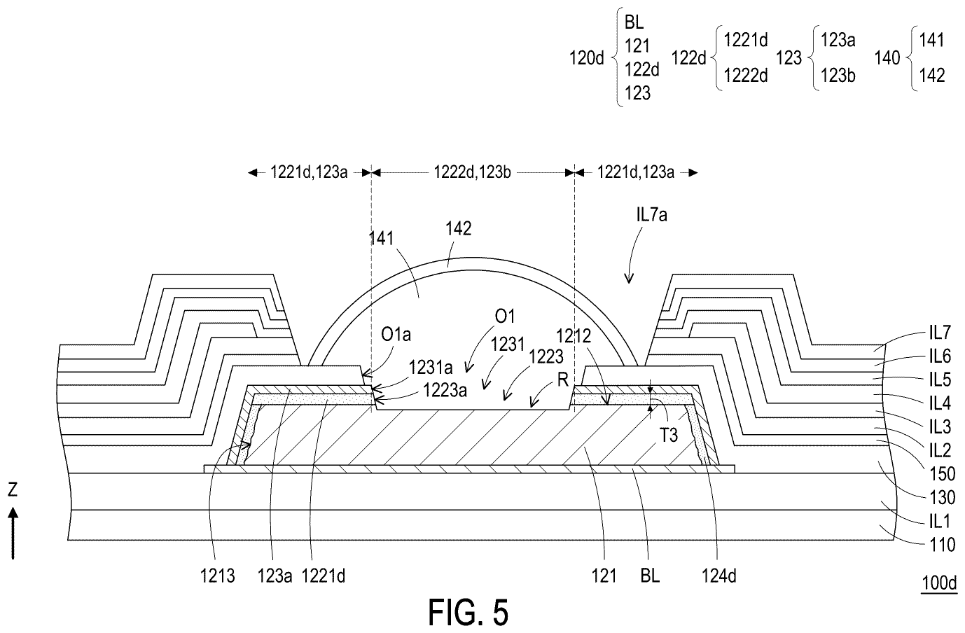

FIG. 5 is a partial cross-sectional schematic view of the electronic device in the fifth embodiment of the disclosure. Referring to FIG. 5 and FIG. 4A to FIG. 4B at the same time, the electronic device 100d of this embodiment is similar to the electronic device 100c in FIG. 4A to FIG. 4B. The difference between the two is: in the electronic device 100d of this embodiment, the material of the second layer 122d of the conductive structure 120d is different from the material of the first layer 121 and the third layer 123, and the second layer 122d is not the intermetallic compound layer of the first layer 121 and the third layer 123.

Specifically, referring to FIG. 5, in this embodiment, the second layer 122d is provided on the second surface 1212 of the first layer 121, and the second layer 122d is provided between the first layer 121 and the third layer 123. The second layer 122d has a continuous part 1221d and a discontinuous part 1222d. The discontinuous part 1222d of the second layer 122d includes the opening 1223.

In this embodiment, the thickness T3 of the second layer 122d may be, for example, 0.01 micron to 0.5 micron, but is not limited thereto. The thickness T3 is, for example, the thickness of the second layer 122d measured along the normal direction Z of the substrate 110. In this embodiment, the material of the second layer 122d may include molybdenum, molybdenum alloy, copper alloy, other suitable metal materials or combinations of the foregoing, but is not limited thereto.

In this embodiment, the material of the second layer 122d does not diffuse toward the first layer 121 or the third layer 123 due to the subsequent high-temperature process. Thus, the material of the second layer 122d may be used to prevent the third layer 123 from diffusing toward the first layer 121 in the subsequent high-temperature process. Thus, this embodiment may avoid the formation of an intermetallic compound layer between the first layer 121 and the third layer 123 by providing the second layer 122d that does not diffuse due to the high-temperature process, then a part of the second layer 122d is removed and a part of the first layer 121 is exposed, thereby forming the conductive member 140 in the recess R, in the opening 1223, in the opening 1231, in the first opening O1, and on the first passivation layer 130, so that the conductive member 140 may be in contact with and be formed on the first layer 121.

In this embodiment, the first layer 121 further include a lateral surface 1213 that may connect the first surface 1211 and the second surface 1212. Since the third layer 123 of this embodiment may also be provided on the lateral surface 1213 of the first layer 121, and the second layer 122d is not provided on the lateral surface 1213 of the first layer 121, the third layer 123 provided on the lateral surface 1213 diffuses toward the first layer 121 in the subsequent high-temperature process, and the fourth layer 124d is formed on the lateral surface 1213. The fourth layer 124d is the intermetallic compound layer of the first layer 121 and the third layer 123.

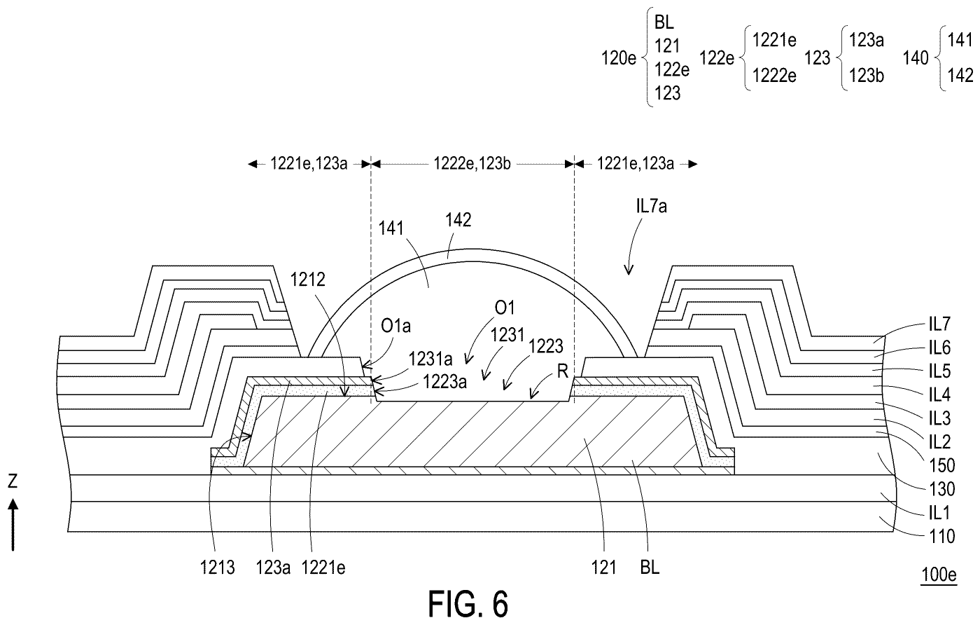

FIG. 6 is a partial cross-sectional schematic view of the electronic device in the sixth embodiment of the disclosure. Referring to FIG. 6 and FIG. 5 at the same time, the electronic device 100e of this embodiment is similar to the electronic device 100d in FIG. 5. The difference between the two is: in the electronic device 100e of this embodiment, the second layer 122e of the conductive structure 120e may be provided on the second surface 1212 and the lateral surface 1213 of the first layer 121.

Specifically, referring to FIG. 5, in this embodiment, the second layer 122e has a continuous part 1221e and a discontinuous part 1222e. The continuous part 1221e of the second layer 122e may be provided on the second surface 1212 and the lateral surface 1213 of the first layer 121; thus, the second layer 122e is used to block the third layer 123 from diffusing toward the first layer 121 in the subsequent high-temperature process to form an intermetallic compound layer. The discontinuous part 1222e of the second layer 122e includes the opening 1223.

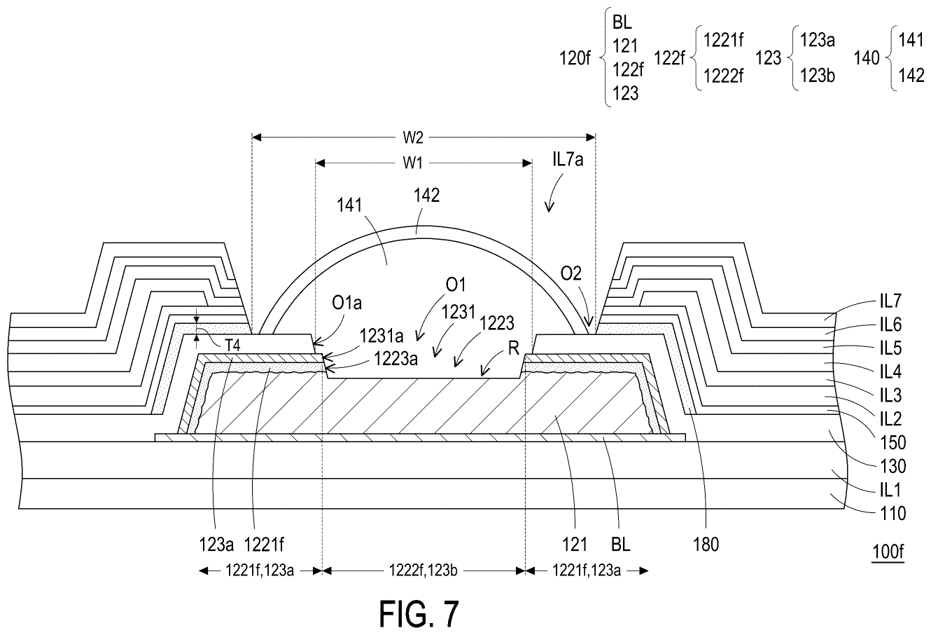

FIG. 7 is a partial cross-sectional schematic view of the electronic device in the seventh embodiment of the disclosure. Referring to FIG. 7 and FIG. 2 at the same time, the electronic device 100f of this embodiment is similar to the electronic device 100a in FIG. 2. The difference between the two is: the electronic device 100f of this embodiment further includes an interlayered metal layer 180.

Specifically, referring to FIG. 7, the second layer 122f of the conductive structure 120f has a continuous part 1221f and a discontinuous part 1222f. The discontinuous part 1222f of the second layer 122f includes the opening 1223.

In this embodiment, the interlayered metal layer 180 is provided at the junction between the second passivation layer 150 and the first passivation layer 130. In addition, since the interlayered metal layer 180 may also be provided between the second passivation layer 150 and the first layer 121, the adhesion between the second passivation layer 150 and the first layer 121 may be increased to reduce the risk of peeling between the second passivation layer 150 and the first layer 121 due to the subsequent high-temperature process.

In this embodiment, the interlayered metal layer 180 has a second opening O2, and the second opening O2 may overlap the first opening O1. In the profile of the electronic device 100f, the first opening O1 has a width W1, the second opening O2 has a width W2, and the width W2 of the second opening O2 may be greater than the width W1 of the first opening O1. The width W1 is, for example, the width measured along direction X of the first opening O1, and width W2 is, for example, the width measured along direction X of the second opening O2. The direction X and the normal direction Z are respectively different directions. The direction X is, for example, the horizontal direction in FIG. 7, and the direction X may be substantially perpendicular to the normal direction Z, but is not limited thereto.

In this embodiment, the thickness T4 of the interlayered metal layer 180 may be, for example, 0.01 micron to 0.5 micron, but is not limited thereto. The thickness T4 is, for example, the thickness of the interlayered metal layer 180 measured along the normal direction Z of the substrate 110. In this embodiment, the material of the interlayered metal layer 180 may include molybdenum, molybdenum alloy, copper alloy, other suitable metal materials or combinations of the foregoing, but is not limited thereto. In addition, in this embodiment, the interlayered metal layer 180 may be regarded as a floating metal, but is not limited thereto.

Different from the manufacturing method of the electronic device 100a in FIG. 2, in the manufacturing method of the electronic device 100f of this embodiment: after stacking the stacked structure (the bottom layer BL, the first layer 121, and the third layer 123) and the first passivation layer 130 and before forming the first transistor TFT1 (or the second transistor TFT2) (i.e., before forming the second layer 122f), the first opening O1 of the first passivation layer 130, the opening 1231 of the third layer 123, and the recess R of the first layer 121 are first formed by etching; next, after forming the interlayered metal layer material on the first passivation layer 130, in the first opening O1, in the opening 1231, and in the recess R, the second passivation layer 150 is formed. In this way, the second passivation layer 150 may be prevented from contacting the first layer 121 through the configuration of the interlayered metal layer material, and the adhesion between the second passivation layer 150 and the first layer 121 may be increased; afterwards, after forming the first transistor TFT1 (or the second transistor TFT2), etching is used to form the opening IL7a of the dielectric layer IL7 and the second opening O2 of the interlayered metal layer 180.

Since the conductive member is not easily formed directly on the intermetallic compound layer, in the electronic device 100e of this embodiment, by forming the opening 1231 of the third layer 123 through etching before forming the second layer 122f containing the intermetallic compound, a part of the first layer 121 may be exposed and the formation of an intermetallic compound layer above the first layer 121 corresponding to the first opening O1 (or the opening 1231) in the subsequent high-temperature process may be avoided. Thus, the conductive member 140 may be formed in the recess R, in the opening 1223, in the opening 1231, in the first opening O1, and on the first passivation layer 130, and the conductive member 140 may be in contact with the first layer 121.

To sum up, in the electronic device of the disclosure, a part of the intermetallic compound layer is removed, a gap is formed, and a part of the first layer is exposed through increasing the processing time of the micro-etch, so that the conductive member may be in contact with and formed on the first layer. In addition, the intermetallic compound layer between the first opening (or the opening of the third layer) and the first layer is removed by wet etch, and a part of the first layer is exposed, so that the conductive member may be in contact with and formed on the first layer. In addition, by forming the opening of the third layer through etching before forming the second layer containing the intermetallic compound, a part of the first layer may be exposed, so that the conductive member may be in contact with and formed on the first layer. In addition, by providing the second layer material that does not diffuse due to the high-temperature processes, the formation of an intermetallic compound layer between the first layer and the third layer may be avoided, and the conductive member may be in contact with and formed on the first layer after a part of the second layer is removed and a part of the first layer is exposed.

Finally, it should be noted that the foregoing embodiments are only used to illustrate the technical solutions of the disclosure, but not to limit the disclosure; although the disclosure has been described in detail with reference to the foregoing embodiments, persons of ordinary skill in the art should understand that the technical solutions described in the foregoing embodiments can still be modified, or parts or all of the technical features thereof can be equivalently replaced; however, these modifications or substitutions do not deviate the essence of the corresponding technical solutions from the scope of the technical solutions of the embodiments of the disclosure.

What is claimed is:

1. An electronic device, comprising:
a substrate;
a conductive structure, provided on the substrate and having at least one discontinuous part;
a first passivation layer, provided on the conductive structure and having a first opening; and
an electronic component, provided on the conductive structure and electrically connected to the conductive structure through the first opening,
wherein the at least one discontinuous part overlaps the first opening.

2. The electronic device according to claim 1, wherein the conductive structure comprises:
a first layer;
a second layer, provided on the first layer and having at least one discontinuous part; and
a third layer, provided on the second layer and having other discontinuous part,
wherein the at least one discontinuous part and the other discontinuous part overlap the first opening.

3. The electronic device according to claim 2, wherein the second layer is an intermetallic compound layer of the first layer and the third layer.

4. The electronic device according to claim 2, wherein the at least one discontinuous part comprises a plurality of gaps.

5. The electronic device according to claim 2, wherein the gaps expose a part of the first layer.

6. The electronic device according to claim 2, wherein the at least one discontinuous part has an opening, and the opening exposes a part of the first layer.

7. The electronic device according to claim 6, wherein the other discontinuous part has other opening, and a side wall of the other opening does not cut flush with a side wall of the opening.

8. The electronic device according to claim 2, wherein the first layer has a recess.

9. The electronic device according to claim 8, wherein the recess overlaps the first opening, the other discontinuous part, and the at least one discontinuous part.

10. The electronic device according to claim 8, wherein in a profile, the recess is not aligned with the first opening.

11. The electronic device according to claim 2, wherein the other discontinuous part has other opening, and a side wall of the other opening does not cut flush with a side wall of the first opening.

12. The electronic device according to claim 2, wherein a thickness of the first layer is greater than a thickness of the third layer.

13. The electronic device according to claim 2, further comprising:
a conductive member, provided on the first passivation layer and in the first opening and in contact with the first layer of the conductive structure.

14. The electronic device according to claim 2, wherein the other discontinuous part has other opening, and the first opening is not aligned with the other opening.

15. The electronic device according to claim 2, wherein a material of the second layer is different from materials of the first layer and the third layer.

16. The electronic device according to claim 15, wherein the first layer has a first surface, a second surface, and a lateral surface, the third layer is provided on the first surface and the lateral surface, and the electronic device further comprises:
a fourth layer, provided on the lateral surface, wherein the fourth layer is an intermetallic compound layer of the first layer and the third layer.

17. The electronic device according to claim 15, wherein the first layer has a first surface, a second surface, and a lateral surface, and the second layer is provided on the first surface and the lateral surface.

18. The electronic device according to claim 1, further comprising:
a second passivation layer; and
an interlayered metal layer, provided between the first passivation layer and the second passivation layer,
wherein the interlayered metal layer has a second opening, and the second opening overlaps the first opening.

19. The electronic device according to claim 18, wherein in a profile, a width of the second opening is greater than a width of the first opening.

20. The electronic device according to claim 18, wherein a roughness of a surface of the first passivation layer is greater than a roughness of a surface of the second passivation layer.
